(19) United States
(12) Patent Application Publication
(10) Pub. No.: US 2025/0185470 A1
(43) Pub. Date: Jun. 5, 2025

(54) DISPLAY DEVICE AND MANUFACTURING METHOD OF DISPLAY DEVICE

(71) Applicant: Japan Display Inc., Tokyo (JP)

(72) Inventors: Sho YANAGISAWA, Tokyo (JP); Hideyuki TAKAHASHI, Tokyo (JP)

(73) Assignee: Japan Display Inc., Tokyo (JP)

(21) Appl. No.: 18/969,706

(22) Filed: Dec. 5, 2024

(30) Foreign Application Priority Data
Dec. 5, 2023 (JP) 2023-205390

(51) Int. Cl. H10K 59/122; H10K 59/12; H10K 59/131

(52) U.S. Cl. CPC H10K 59/122; H10K 59/1201; H10K 59/131

(57) ABSTRACT

A display device can include a first inorganic insulating layer, an organic insulating layer on the first inorganic insulating layer, a lower electrode on the organic insulating layer, an organic layer on the lower electrode, an upper electrode on the organic layer, a second inorganic insulating layer which is on the organic insulating layer and has an aperture which exposes an edge portion of the organic insulating layer, a plurality of lines intersecting with the edge portion, and a plurality of protective layers intersecting with the edge portion. One of the protective layers can face one of the lines and can overlap the first inorganic insulating layer exposed from the organic insulating layer in the aperture.

### CROSS-REFERENCE TO RELATED APPLICATION

This application is based upon and claims the benefit of priority from Japanese Patent Application No. 2023-205390, filed Dec. 5, 2023, the entire contents of which are incorporated herein by reference.

### FIELD

Embodiments described herein relate generally to a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

### SUMMARY

A display device can include a first inorganic insulating layer, an organic insulating layer on the first inorganic insulating layer, a lower electrode on the organic insulating layer, an organic layer on the lower electrode, an upper electrode on the organic layer, a second inorganic insulating layer which is on the organic insulating layer and has an aperture which exposes an edge portion of the organic insulating layer, a plurality of lines intersecting with the edge portion, and a plurality of protective layers intersecting with the edge portion. One of the protective layers can face one of the lines and can overlap the first inorganic insulating layer exposed from the organic insulating layer in the aperture.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a schematic cross-sectional view of the display device DSP along the C-D line of FIG. 1.

FIG. 5 is a plan view showing a configuration example of a mother substrate 100.

FIG. 6 is a plan view showing a configuration example of the area 100A of the mother substrate 100 shown in FIG. 5.

FIG. 7 is a cross-sectional view showing a configuration example of the mother substrate 100 along the E-F line of FIG. 6.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining the manufacturing method of the display device DSP.

FIG. 17 is a diagram for explaining the manufacturing method of the display device DSP.

FIG. 18 is a diagram for explaining the manufacturing method of the display device DSP.

FIG. 19 is a diagram for explaining the manufacturing method of the display device DSP.

FIG. 20 is a diagram for explaining the manufacturing method of the display device DSP.

FIG. 21 is a cross-sectional view for explaining the problems of a comparative example.

FIG. 22 is a diagram for explaining one of the effects of the embodiment.

FIG. 23 is a cross-sectional view for explaining the problems of the comparative example.

FIG. 24 is a diagram showing another configuration example of the display device DSP.

FIG. 25 is a plan view showing a configuration example of the mother substrate 100.

FIG. 26 is a plan view showing the substrate after the mother substrate 100 is cut along primary cut lines CL1.

### DETAILED DESCRIPTION

One or more embodiments described herein may be regarded as having an aim, among one or more aims, to provide a display device and a manufacturing method of a display device such that the reduction in reliability can be minimized or prevented.

In general, according to at least one embodiment, a display device can comprise a substrate, a first inorganic insulating layer provided over a display area which displays an image and a surrounding area located on an external side relative to the display area above the substrate, an organic insulating layer provided on the first inorganic insulating layer, a lower electrode provided on the organic insulating layer in the display area, an organic layer which is provided on the lower electrode and includes a light emitting layer, an upper electrode provided on the organic layer, a second inorganic insulating layer which is provided on the organic insulating layer and has an aperture which exposes an edge portion of the organic insulating layer in the surrounding area, a plurality of lines which are provided between the substrate and the first inorganic insulating layer and intersect with the edge portion in plan view, and a plurality of protective layers which intersect with the edge portion in plan view. One of the protective layers faces one of the lines and overlaps the first inorganic insulating layer exposed from the organic insulating layer in the aperture.

According to another embodiment, a manufacturing method of a display device can comprise forming a line above a substrate, forming a first inorganic insulating layer on the line, forming an organic insulating layer on the first inorganic insulating layer, forming a lower electrode on the organic insulating layer, forming a protective layer which faces the line and overlaps the first inorganic insulating layer exposed from the organic insulating layer, forming a second inorganic insulating layer which covers the organic insulating layer and the protective layer, forming an aperture which overlaps an edge portion of the organic insulating layer in the second inorganic insulating layer, forming an organic layer on the lower electrode, and forming an upper electrode on the organic layer.

One or more embodiments can provide a display device and a manufacturing method of a display device such that the reduction in reliability can be minimized or prevented.

Embodiments will be described with reference to the accompanying drawings.

The present disclosure presents examples, and proper changes in keeping with the spirit of according to one or more embodiments of the present disclosure, come within the scope of the present disclosure. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of one or more embodiments according to the disclosure. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. The first direction X and the second direction Y are directions parallel to the main surface of the substrate constituting the display device. The third direction Z corresponds to the thickness direction of the display device (the normal direction of the main surface).

The display device of the present embodiment can be an organic electroluminescent display device comprising an organic light emitting diode (OLED) as a display element, and could be mounted on a television, a personal computer, a vehicle-mounted device, a tablet, a smartphone, a mobile phone, etc.

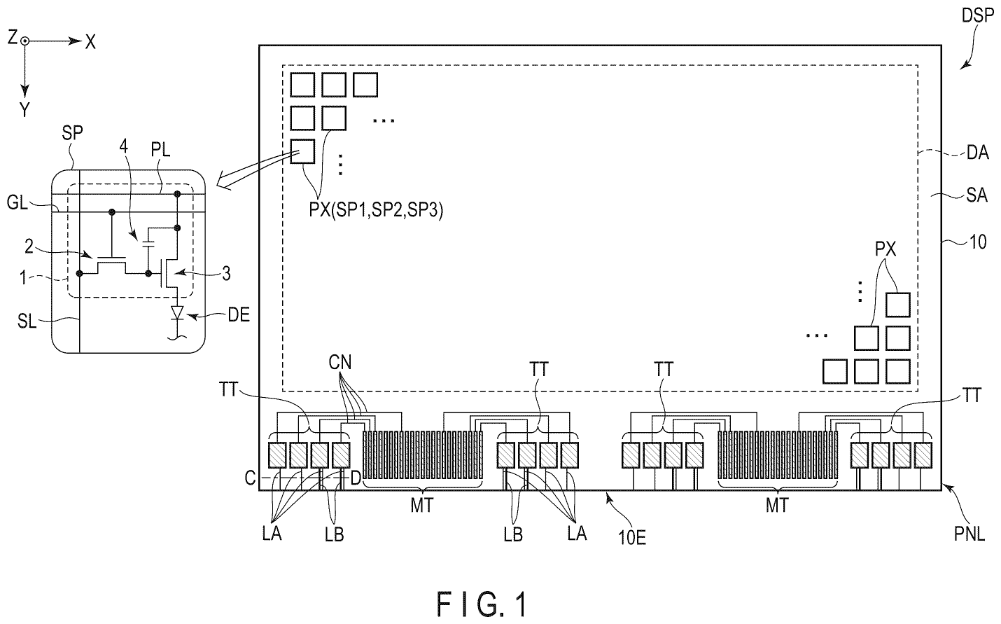

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. The substrate 10 of the example shown in the figure has long sides parallel to a first direction X and short sides parallel to a second direction Y. It should be noted that the shape of the substrate 10 in plan view is not limited to a rectangle and may be another shape such as a square, a circle or an oval.

The display area DA comprises a plurality of pixels PX arrayed in matrix in the first direction X and the second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and the drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to an anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA comprises a plurality of mount terminals MT and a plurality of inspection terminals TT. The mount terminals MT are terminals electrically connected to signal sources such as flexible printed circuits and IC chips and are electrically connected to the various lines (scanning lines, signal lines, power lines, lines for touch sensors and the like) of the display area DA. The inspection terminals TT are terminals electrically connected to inspection devices which confirm the short circuit or breaking of various lines, the operation of various circuits, etc. For example, these inspection terminals TT are electrically connected to the mount terminals MT via connection lines CN. Each of the inspection terminals TT is connected to at least one of a plurality of lines LA and LB extending toward a substrate end 10E. In other words, the inspection terminals TT include inspection terminals TT each of which is connected to only the line LA, and inspection terminals TT each of which is connected to both the line LA and the line LB.

In the example shown in the figure, all of the mount terminals MT and the inspection terminals TT are provided along the substrate end 10E and are arranged in the first direction X.

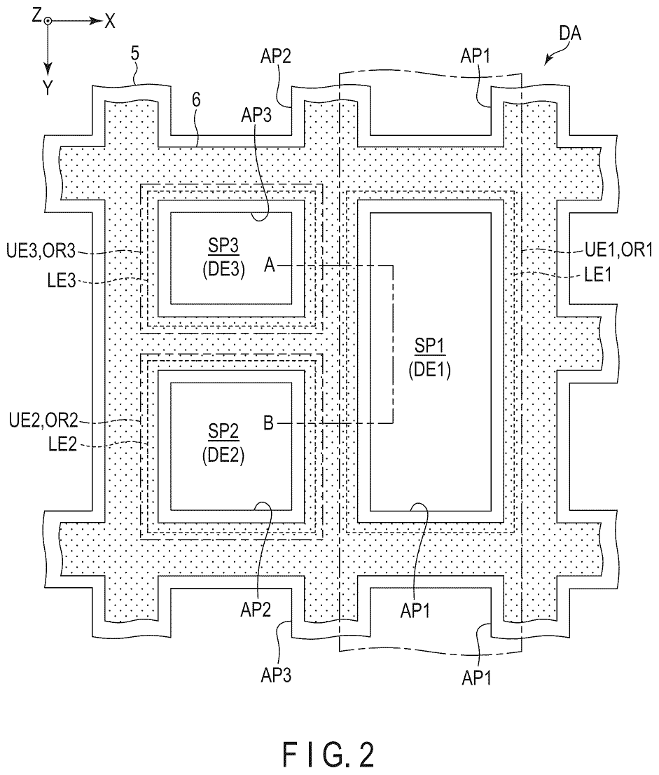

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An insulating layer 5 and a partition 6 are provided in the display area DA. The insulating layer 5 has apertures AP1, AP2 and AP3 in subpixels SP1, SP2 and SP3, respectively. The insulating layer 5 having these apertures AP1, AP2 and AP3 may be called a rib.

The partition 6 overlaps the insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the insulating layer 5. The partition 6 is conductive and is electrically connected to, of the mount terminals MT shown in FIG. 1, each mount terminal MT having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The peripheral portion of the lower electrode LE1 is covered with the insulating layer 5. The lower electrode LE1, the organic layer OR1 and the upper electrode UE1 are surrounded by the partition 6 in plan view. The peripheral portion of each of the organic layer OR1 and the upper electrode UE1 overlaps the insulating layer 5 in plan view. The organic layer OR1 includes a light emitting layer which emits light in, for example, a blue wavelength range.

The display element DE2 of subpixel SP2 comprises a lower electrode LE2, an upper electrode UE2 and an organic layer OR2 overlapping the aperture AP2. The peripheral portion of the lower electrode LE2 is covered with the insulating layer 5. The lower electrode LE2, the organic layer OR2 and the upper electrode UE2 are surrounded by the partition 6 in plan view. The peripheral portion of each of the organic layer OR2 and the upper electrode UE2 overlaps the insulating layer 5 in plan view. The organic layer OR2 includes a light emitting layer which emits light in, for example, a green wavelength range.

The display element DE3 of subpixel SP3 comprises a lower electrode LE3, an upper electrode UE3 and an organic layer OR3 overlapping the aperture AP3. The peripheral portion of the lower electrode LE3 is covered with the insulating layer 5. The lower electrode LE3, the organic layer OR3 and the upper electrode UE3 are surrounded by the partition 6 in plan view. The peripheral portion of each of the organic layer OR3 and the upper electrode UE3 overlaps the insulating layer 5 in plan view. The organic layer OR3 includes a light emitting layer which emits light in, for example, a red wavelength range.

In the example shown in the figure, the outer shapes of the lower electrodes LE1, LE2 and LE3 are shown by dotted lines, and the outer shapes of the organic layers OR1, OR2 and OR3 and the upper electrodes UE1, UE2 and UE3 are shown by the one-dot chain lines. It should be noted that the outer shape of each of the lower electrodes, the organic layers and the upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

The lower electrode LE1 is electrically connected to the pixel circuit 1 (see FIG. 1) of subpixel SP1. The lower electrode LE2 is electrically connected to the pixel circuit 1 of subpixel SP2. The lower electrode LE3 is electrically connected to the pixel circuit 1 of subpixel SP3.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

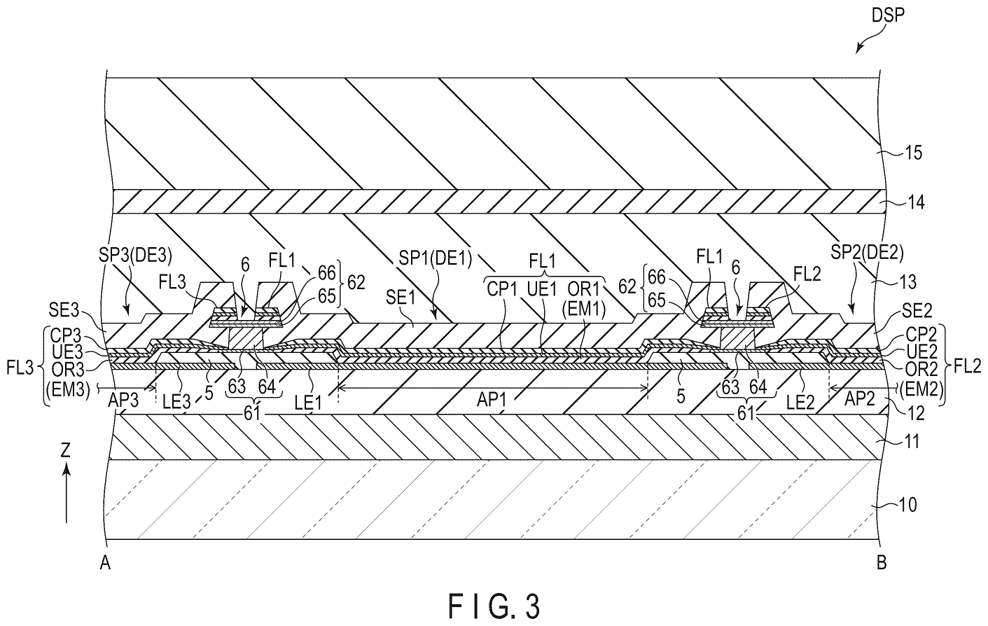

FIG. 3 is a schematic cross-sectional view of the display device DSP along the A-B line of FIG. 2.

A circuit layer 11 is provided on the substrate 10. The circuit layer 11 includes various circuits such as the pixel circuits 1 shown in FIG. 1, various lines such as the scanning lines GL, the signal lines SL and the power lines PL and various insulating layers. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The insulating layer 5 is an inorganic insulating layer and is provided on the insulating layer 12 and the lower electrodes LE1, LE2 and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the insulating layer 5. The lower electrodes LE1, LE2 and LE3 are connected to the pixel circuits 1 of subpixels SP1, SP2 and SP3, respectively, through contact holes provided in the insulating layer 12. It should be noted that the contact holes of the insulating layer 12 are omitted in FIG. 3.

The partition 6 includes a conductive lower portion 61 provided on the insulating layer 5 and an upper portion 62 provided on the lower portion 61. The upper portion 62 has a width greater than that of the lower portion 61. The both end portions of the upper portion 62 protrude relative to the side surfaces of the lower portion 61. This shape of the partition 6 is called an overhang shape.

In the example shown in the figure, the lower portion 61 has a conductive layer 63 provided on the insulating layer 5 and a conductive layer 64 provided on the conductive layer 63. For example, the conductive layer 63 is formed so as to be thinner than the conductive layer 64. In the example shown in the figure, the both end portions of the conductive layer 63 protrude from the side surfaces of the conductive layer 64.

The upper portion 62 has a thin film 65 provided on the conductive layer 64 and a thin film 66 provided on the thin film 65. The both end portions of the thin films 65 and 66 protrude from the side surfaces of the conductive layer 64. Each of the thin films 65 and 66 may be a conductive layer or an insulating layer.

The organic layer OR1 is in contact with the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and is in contact with the lower portion 61.

In the example shown in the figure, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example shown in the figure, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element DE1).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element DE2).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element DE3).

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The end portions of the sealing layers SE1, SE2 and SE3 and the end portions of the stacked films FL1, FL2 and FL3 are located on the partition 6. In the example shown in the figure, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The partition 6 and the sealing layers SE1, SE2 and SE3 are covered with a resin layer 13. The resin layer 13 is covered with a sealing layer 14. The sealing layer 14 is covered with a resin layer 15.

Each of the insulating layer 5, the sealing layers SE1, SE2 and SE3 and the sealing layer 14 is formed of, for example, an inorganic insulating material such as silicon nitride (SiNx), silicon oxide (Siox), silicon oxynitride (SiON) or aluminum oxide (Al₂O₃).

The lower portion 61 of the partition 6 is formed of a conductive material and is electrically connected to the upper electrodes UE1, UE2 and UE3. The conductive layer 63 is formed of, for example, a titanium-based material such as titanium or a titanium compound. The conductive layer 64 is formed of a material which is different from the conductive layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The thin film 65 is formed of, for example, a titanium-based material such as titanium or a titanium compound. The thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers. The lower transparent layer functions as an adhesive layer which adheres tightly to the insulating layer 12.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, the insulating layer 12 and the insulating layer 5 shown in the figure are provided over the display area DA and the surrounding area SA.

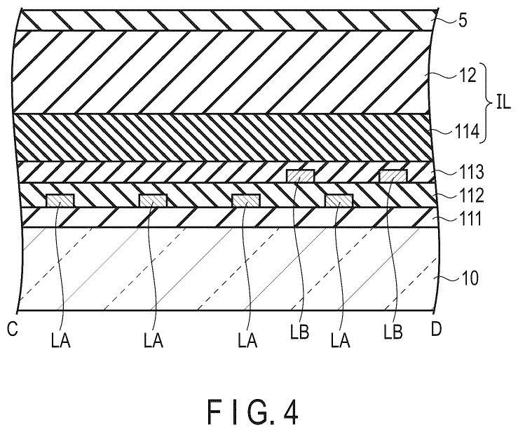

FIG. 4 is a schematic cross-sectional view of the display device DSP along the C-D line of FIG. 1.

An insulating layer 111 is an inorganic insulating layer and is provided on the substrate 10. The lines LA are provided on the insulating layer 111. These lines LA are formed of, for example, a semiconductor such as polycrystalline silicon. An insulating layer 112 is an inorganic insulating layer, is provided on the insulating layer 111 and covers the lines LA. The lines LB are provided on the insulating layer 112. These lines LB are formed of, for example, a metal material such as molybdenum, tungsten, titanium or aluminum. The lines LB are formed of, for example, the same material as the scanning lines GL shown in FIG. 1. An insulating layer 113 is an inorganic insulating layer, is provided on the insulating layer 112 and covers the lines LB. An insulating layer 114 is an organic insulating layer and is provided on the insulating layer 113.

Each of the insulating layers 111, 112 and 113 is formed of, for example, an inorganic insulating material such as silicon nitride (SiNx), silicon oxide (SiOx) or silicon oxynitride (SiON).

These insulating layers 111, 112, 113 and 114 and the lines LA and LB are included in the circuit layer 11 shown in FIG. 3.

The insulating layer 12 is provided on the insulating layer 114. A stacked body consisting of the insulating layer 12 and the insulating layer 114 is collectively called an organic insulating layer IL.

The insulating layer 5 is provided on the insulating layer 12.

Now, this specification explains a mother substrate 100 for a display device (hereinafter, simply referred to as a mother substrate 100) for manufacturing a plurality of display devices DSP in a lump.

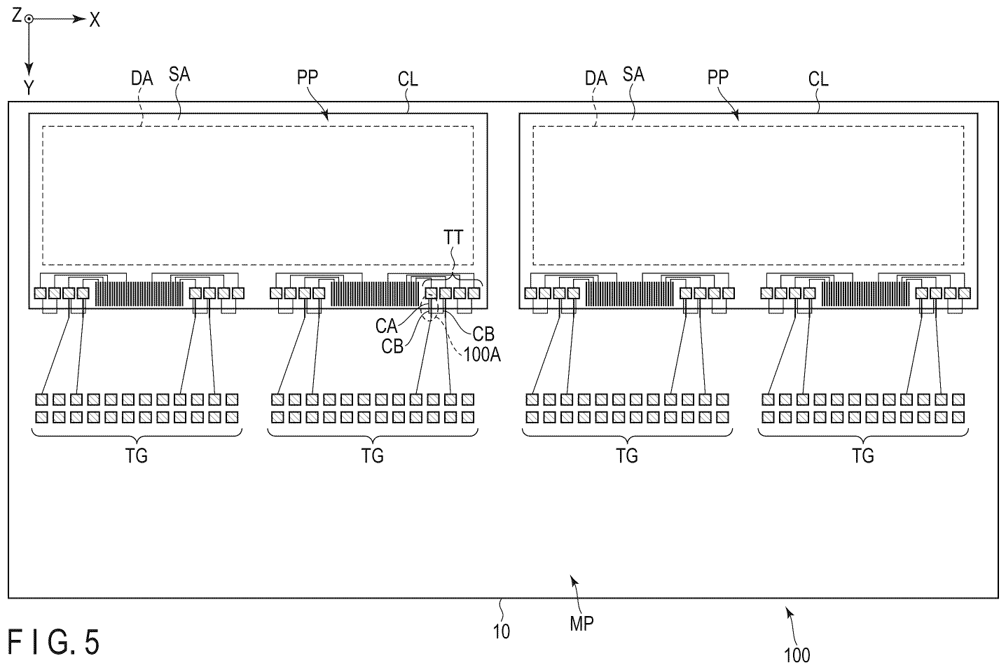

FIG. 5 is a plan view showing a configuration example of the mother substrate 100.

The mother substrate 100 comprises a plurality of panel portions PP and a margin portion MP located on an external side relative to these panel portions PP on a large substrate 10. The large substrate 10 is formed into, for example, a rectangular shape. The example of the figure shows two panel portions PP as a plurality of panel portions PP. However, more panel portions may be arrayed in matrix in the first direction X and the second direction Y. The panel portions PP are extracted by cutting the mother substrate 100 along cut lines CL. Each of the extracted panel portions PP corresponds to the display panel PNL shown in FIG. 1 and comprises the display area DA and the surrounding area SA.

The margin portion MP comprises, for example, a plurality of TEG terminals TG electrically connected to a test element group etc.

Each connection line CA is provided over the panel portion PP and the margin portion PP and electrically connects adjacent inspection terminals TT to each other. Each connection line CB is provided in the margin portion MP and electrically connects the TEG terminal TG and the inspection terminal TT to each other.

When the mother substrate 100 is cut along the cut lines CL, part of each connection line CA remains in the display panel PNL as the line LA shown in FIG. 1, and part of each connection line CB remains in the display panel PNL as the line LB shown in FIG. 1.

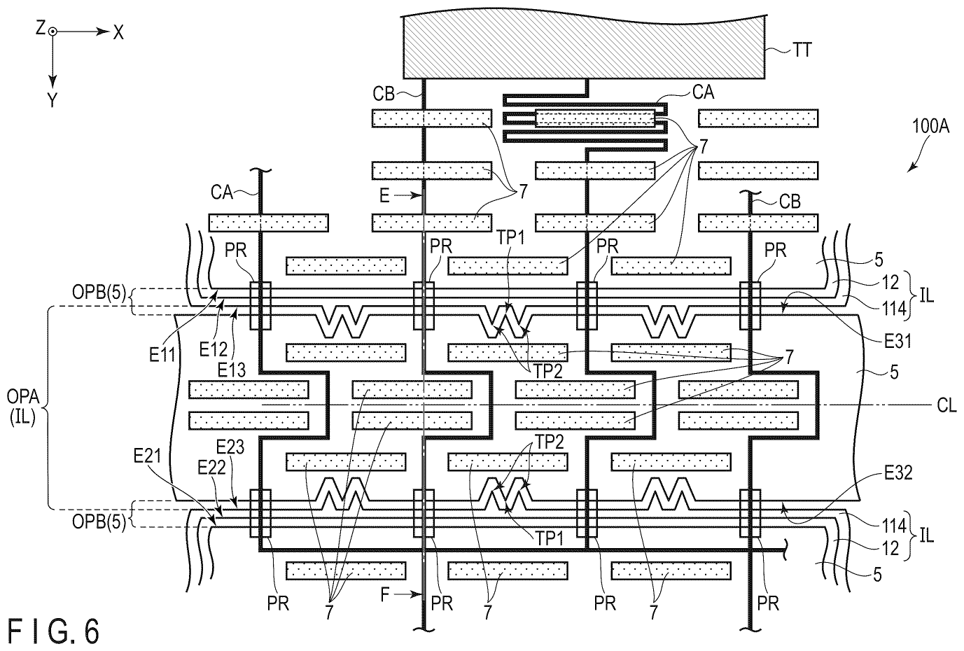

FIG. 6 is a plan view showing a configuration example of the area 100A of the mother substrate 100 shown in FIG. 5.

The cut line CL shown by the two-dot chain line in FIG. 6 could be the outer shape of the display panel PNL shown in FIG. 1. The organic insulating layer IL has an aperture OPA along the outer shape of the panel portion PP. The cut line CL overlaps the aperture OPA. The aperture OPA is a penetration portion in the organic insulating layer IL and exposes the base of the organic insulating layer IL.

In the area 100A shown in the figure, the insulating layer 5 has edge portions E11, E21, E31 and E32. The insulating layer 12 has edge portions E12 and E22. The insulating layer 114 has edge portions E13 and E23. The edge portion E12 is located between the edge portion E11 and the edge portion E13. The edge portion E22 is located between the edge portion E21 and the edge portion E23. Thus, in the organic insulating layer IL, the insulating layer 114 extends toward the cut line CL relative to the insulating layer 12. The aperture OPA is formed between the edge portions E13 and E23 which face each other across the intervening cut line CL.

The insulating layer 5 has apertures OPB which expose the edge portions E12 and E22 of the insulating layer 12 and the edge portions E13 and E23 of the insulating layer 114. The insulating layer 5 is partly located in the aperture OPA. The apertures OPB partly overlap the aperture OPA in plan view.

The connection line CA and the connection line CB are connected to the inspection terminal TT. The connection line CA has a meandering portion, and thus, the resistance is made high.

The connection line CA and the connection line CB intersect with each of the edge portions E11, E12, E13, E31, E32, E23, E22 and E21 in plan view. The connection line CA and the connection line CB overlap surrounding partitions 7 in the area which overlaps the organic insulating layer IL. In the area (aperture OPA) which does not overlap the organic insulating layer IL, the connection line CA or CB does not overlap the surrounding partitions 7, and the connection lines CA and CB are bent so as to bypass the surrounding partitions 7. The details of the surrounding partitions 7 are described later.

Each of protective layers PR intersects with the edge portions E11, E12, E13 and E31 or the edge portions E32, E23, E22 and E21 and overlaps the connection line CA or the connection line CB in plan view. More specifically, one of the protective layers PR is provided at the intersection of the connection line CA and the edge portions E11, E12, E13 and E31, and another protective layer PR is provided at the intersection of the connection line CA and the edge portions E32, E23, E22 and E21. Further, one of the protective layers PR is provided at the intersection of the connection line CB and the edge portions E11, E12, E13 and E31, and another protective layer PR is provided at the intersection of the connection line CB and the edge portions E32, E23, E22 and E21.

The edge portion E13 and the edge portion E31 face each other across an intervening gap in plan view. Each of the edge portions E13 and E31 is formed so as to have a zigzag shape between the connection line CA and the connection line CB.

In the example shown in the figure, the edge portion E31 and the edge portion E13 extend in the first direction X and face each other across an intervening gap in the second direction Y. The edge portion E31 has a taper portion TP1 which is bent so as to taper toward the edge portion E13 between the connection line CA and the connection line CB. The edge portion E13 has taper portions TP2 which are bent so as to taper toward the edge portion E31 between the connection line CA and the connection line CB. The taper portion TP1 is located between two taper portions TP2 and does not overlap the taper portions TP2.

Similarly, the edge portion E23 and the edge portion E32 face each other across an intervening gap. Each of the edge portions E23 and E32 is formed so as to have a zigzag shape between the connection line CA and the connection line CB.

When the area 100A is cut along the cut line CL, the inspection terminal TT remains in the display panel, and the connection line CA between the inspection terminal TT and the cut line CL remains in the display panel as the line LA, and the connection line CB between the inspection terminal TT and the cut line CL remains in the display panel as the line LB.

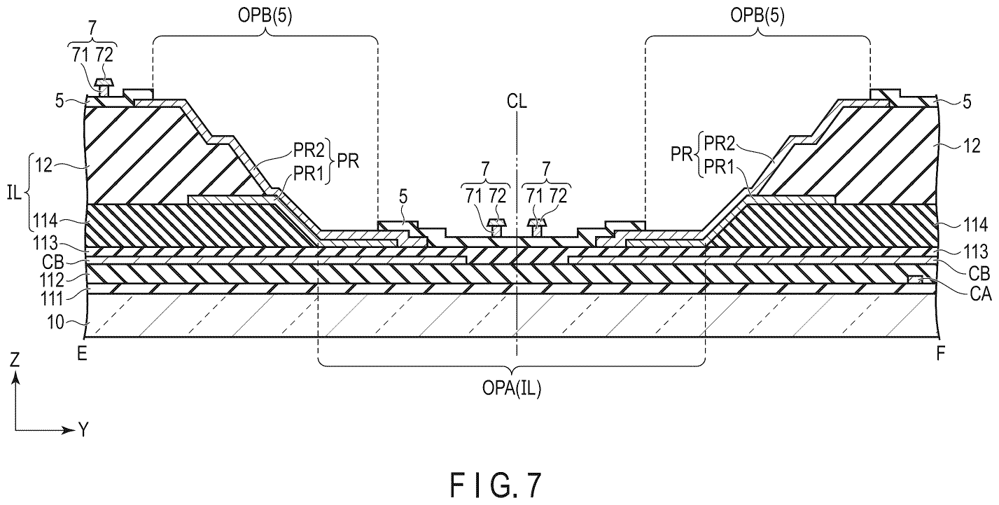

FIG. 7 is a cross-sectional view showing a configuration example of the mother substrate 100 along the E-F line of FIG. 6. Here, FIG. 7 shows a section which includes the overlapping portions of the connection line CB and the protective layers PR.

The connection line CA is provided on the insulating layer 111 and is covered with the insulating layer 112. The connection line CB is provided on the insulating layer 112, is covered with the insulating layer 113 and intersects with the connection line CA.

The insulating layer 114 included in the organic insulating layer IL is provided on the insulating layer 113. The insulating layer 12 is provided on the insulating layer 114. The insulating layer 12 is, for example, thicker than the insulating layer 114. The insulating layer 12 is formed so as to have a stepwise cross section. The insulating layer 12 having this stepwise cross section is formed by adjusting a partial exposure amount. Further, the insulating layer 12 is retracted relative to the insulating layer 114. The slope of the insulating layer 114 and the slope of the insulating layer 12 overlap the aperture OPB. Thus, the organic insulating layer IL has a stepwise cross section in the area overlapping the aperture OPB.

Each protective layer PR faces the connection line CB via the insulating layer 113 in a third direction Z, and overlaps the insulating layer 113 which is exposed from the organic insulating layer IL in the aperture OPB. Although not shown in the figure, in the overlapping portion of the connection line CA and each protective layer PR, similarly, the protective layer PR faces the connection line CA via the insulating layer 113 in the third direction Z, and overlaps the insulating layer 113 which is exposed from the organic insulating layer IL in the aperture OPB.

In the embodiment, each protective layer PR comprises a protective layer PR1 and a protective layer PR2 formed of a material different from that of the protective layer PR1. The protective layer PR2 is provided on the protective layer PR1.

The protective layer PR1 is formed of, for example, a metal material such as molybdenum, tungsten, titanium or aluminum. The protective layer PR1 is in contact with the insulating layer 113 and is in contact with the insulating layer 114 as well. An end portion of the protective layer PR1 is located between the insulating layer 114 and the insulating layer 12. The other end portion of the protective layer PR1 is located between the insulating layer 114 and the protective layer PR2.

The protective layer PR2 is formed of the same material as the lower electrodes LE described above. The protective layer PR2 is in contact with each of the insulating layer 113, the protective layer PR1 and the insulating layer 12. An end portion of the protective layer PR2 is located between the insulating layer 12 and the insulating layer 5. The other end of the protective layer PR2 is located between the insulating layer 113 and the insulating layer 5.

The surrounding partitions 7 are provided on the insulating layer 5 in the area which overlaps the organic insulating layer IL and the area (aperture OPA) which does not overlap the organic insulating layer IL. Each of the surrounding partitions 7 has a lower portion 71 provided on the insulating layer 5 and an upper portion 72 provided on the lower portion 71. Although not described in detail, in a manner similar to that of the lower portion 61, the lower portion 71 is a multilayer body consisting of a conductive layer formed of, for example, a titanium-based material, and a conductive layer formed of, for example, an aluminum-based material. In a manner similar to that of the upper portion 62, the upper portion 72 is a multilayer body consisting of a thin film formed of, for example, a titanium-based material, and a thin film formed of, for example, an oxide conductive material. The upper portion 72 has a width which is greater than that of the lower portion 71. The both end portions of the upper portion 72 protrude relative to the side surfaces of the lower portion 71.

Thus, each of the surrounding partitions 7 has an overhang shape similar to that of the partition 6 shown in FIG. 3. The surrounding partitions 7 can be formed in the same process as the partition 6. In this case, the lower portion 71 and the lower portion 61 are formed using the same material in the same process, and the upper portion 72 and the upper portion 62 are formed using the same material in the same process.

Now, this specification explains the manufacturing method of the display device DSP.

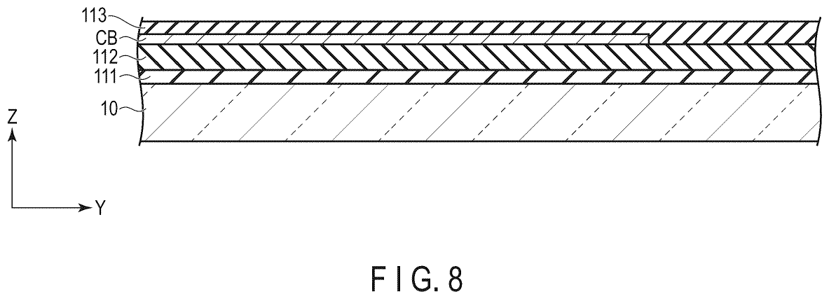

First, as shown in FIG. 8, part of the circuit layer is formed on the substrate 10. Specifically, after the insulating layer 111 is formed on the substrate 10, the connection line CA (not shown here) consisting of a semiconductor is formed on the insulating layer 111. Subsequently, the insulating layer 112 is formed on the connection line CA and the insulating layer 111, and the connection line CB is formed using a metal material on the insulating layer 112. Subsequently, the insulating layer 113 is formed on the connection line CB and the insulating layer 112.

Subsequently, the organic insulating layer IL and the protective layer PR are formed.

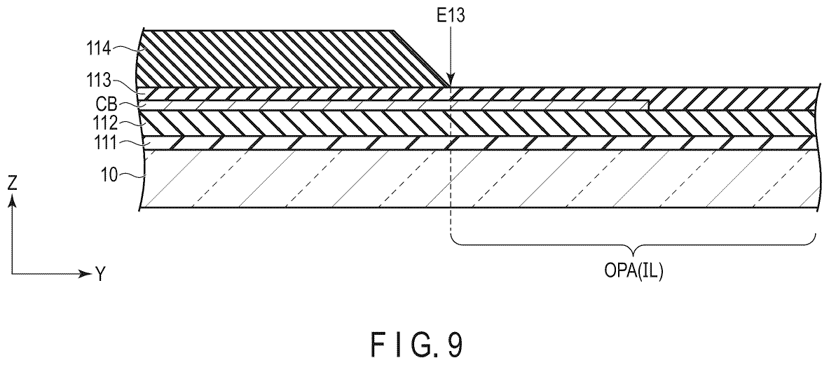

First, as shown in FIG. 9, the insulating layer 114 which is part of the organic insulating layer IL is formed on the insulating layer 113. The edge portion E13 is formed by patterning the insulating layer 114. At this time, the edge portion E13 is formed so as to have a zigzag shape as shown in FIG. 6.

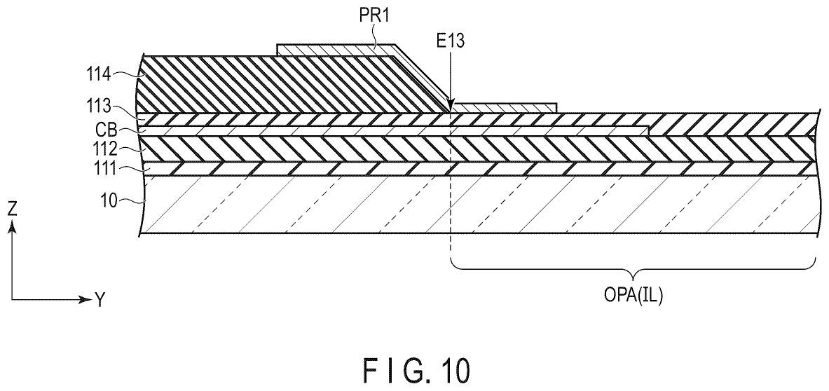

Subsequently, as shown in FIG. 10, as part of the protective layer PR, the protective layer PR1 which intersects with the edge portion E13 immediately above the connection line CB is formed. The protective layer PR1 is in contact with the insulating layer 113 and extends to the upper side of the insulating layer 114. This protective layer PR1 is formed by forming a metal layer on the insulating layer 113 and the insulating layer 114 and patterning the metal layer. The metal layer for forming the protective layer PR1 is, for example, a multilayer body in which a molybdenum-based metal layer is located between a pair of titanium-based metal layers.

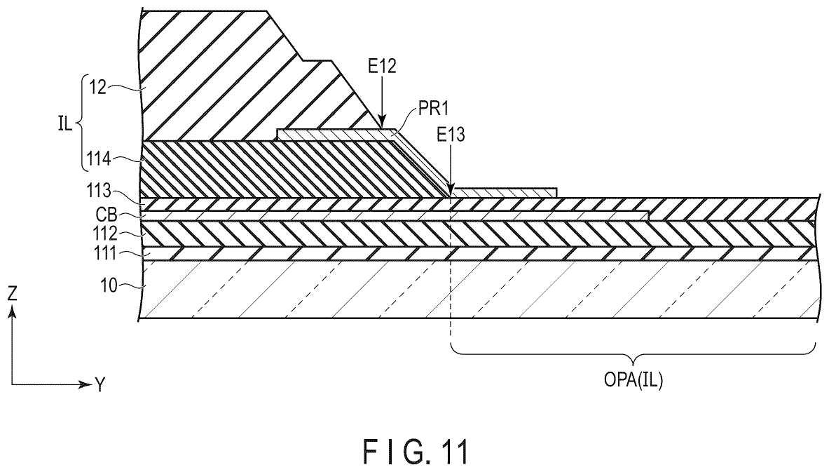

Subsequently, as shown in FIG. 11, the insulating layer 12 which is part of the organic insulating layer IL is formed. A stepwise cross section is formed by adjusting the exposure amount when the insulating layer 12 is patterned. An end portion of the protective layer PR1 is covered near the edge portion E12. The edge portion E12 is retracted relative to the edge portion E13. The aperture OPA of the organic insulating layer IL is defined by the edge portion E13.

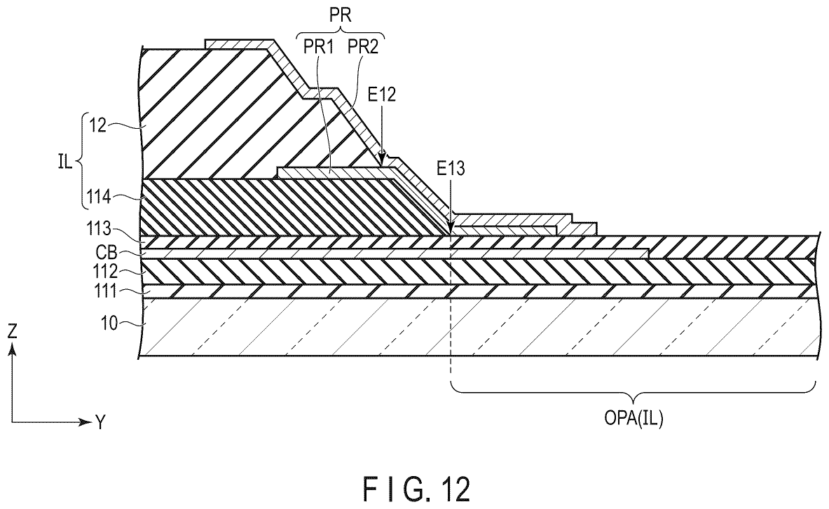

Subsequently, as shown in FIG. 12, as part of the protective layer PR, the protective layer PR2 which intersects with the edge portions E12 and E13 immediately above the connection line CB is formed. The protective layer PR2 is in contact with the insulating layer 113, overlaps the protective layer PR1 and extends to the upper side of the insulating layer 12. This protective layer PR2 is formed at the same time as the lower electrodes by forming a conductive layer for forming the lower electrodes on the insulating layer 113 and the organic insulating layer IL and patterning the conductive layer. The conductive layer for forming the lower electrodes is, for example, a multilayer body in which a silver-based reflective layer is located between a pair of transparent layers (ITO layers).

In this manner, the organic insulating layer IL and the protective layer PR are formed through the process explained with reference to FIG. 9 to FIG. 12.

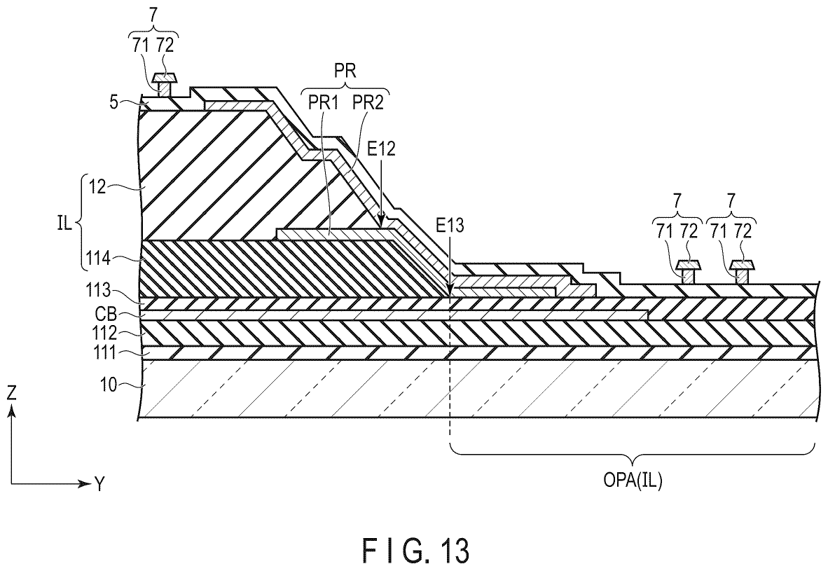

Subsequently, as shown in FIG. 13, the insulating layer 5 is formed so as to cover the organic insulating layer IL and the protective layer PR. Subsequently, the surrounding partitions 7 each of which has the lower portion 71 located on the insulating layer 5 and the upper portion 72 located on the lower portion 71 and protruding from the side surfaces of the lower portion 71 are formed.

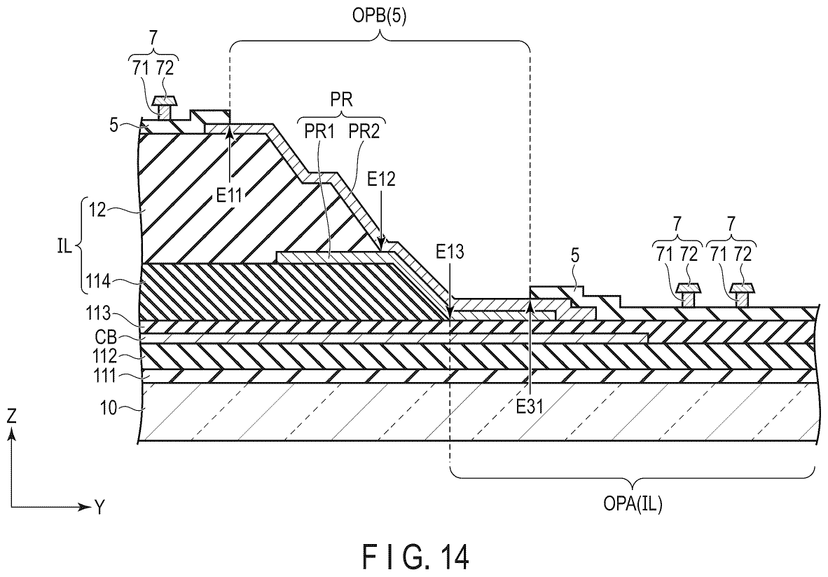

Subsequently, as shown in FIG. 14, the aperture OPB which overlaps the edge portions E12 and E13 is formed by patterning the insulating layer 5. By this process, the edge portions E11 and E31 which define the aperture OPB are formed. At this time, the edge portion E31 is formed so as to have a zigzag shape as shown in FIG. 6.

These insulating layers 111, 112, 113, 114, 12 and 5 are formed in the panel portion as well.

Now, this specification explains the manufacturing method of the display elements in the panel portion. Regarding each figure for explaining the manufacturing method below, the illustration of the lower side of the insulating layer 12 is omitted.

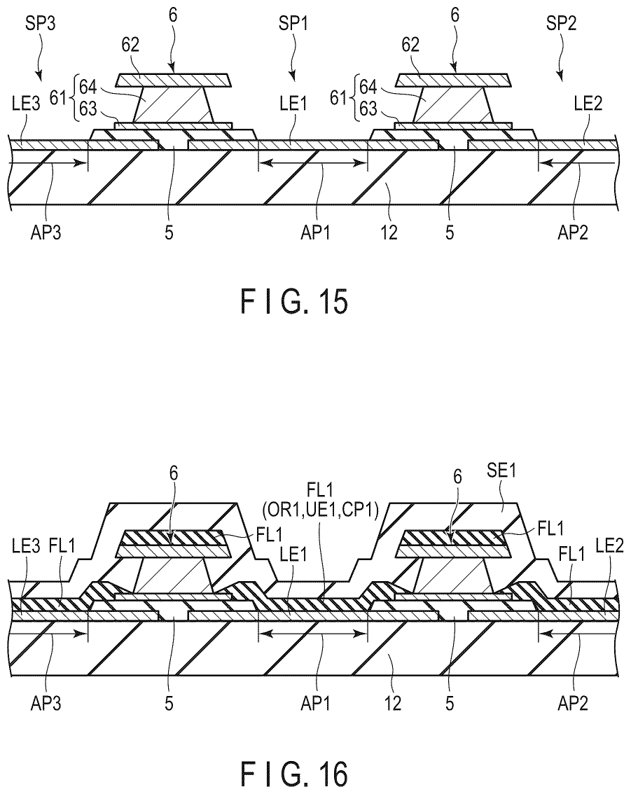

As shown in FIG. 15, the lower electrode LE1 of subpixel SP1, the lower electrode LE2 of subpixel SP2 and the lower electrode LE3 of subpixel SP3 are formed at the same time as the protective layer PR2 as stated above.

The partition 6 is formed at the same time as the surrounding partitions 7 and has the lower portion 61 located on the insulating layer 5 and the upper portion 62 located on the lower portion 61 and protruding from the side surfaces of the lower portion 61. Thus, the lower portion 61 of the partition 6 is formed at the same time as the lower portions 71 of the surrounding partitions 7, and the upper portion 62 is formed at the same time as the upper portions 72.

The apertures AP1, AP2 and AP3 of the insulating layer 5 are formed at the same time as the aperture OPB.

It should be noted that the process of forming the apertures AP1, AP2, AP3 and OPB in the insulating layer 5 may be performed either before the partition 6 and the surrounding partitions 7 are formed or after the partition 6 and the surrounding partitions 7 are formed.

Subsequently, the display element DE1 is formed.

First, as shown in FIG. 16, the stacked film FL1 including the organic layer OR1, the upper electrode UE1 and the cap layer CP1 is formed. The process of forming the stacked film FL1 includes the process of forming the organic layer OR1 which is in contact with the lower electrode LE1 in the aperture AP1, the process of forming the upper electrode UE1 which covers the organic layer OR1 and is in contact with the lower portion 61 of the partition 6, and the process of forming the cap layer CP1 located on the upper electrode UE1. The process of forming the organic layer OR1 includes the process of forming each of the hole injection layer, the hole transport layer, the electron blocking layer, the light emitting layer, the hole blocking layer, the electron transport layer, the electron injection layer and the like. Each of the organic layer OR1, the upper electrode UE1 and the cap layer CP1 is formed by vapor deposition using the partition 6 as a mask. Specifically, the stacked film FL1 is formed by forming the organic layer OR1 including the light emitting layer EM1, the upper electrode UE1 and the cap layer CP1 in order on the lower electrode LE1. The stacked film FL1 is divided into a plurality of portions by the partition 6 having an overhang shape. These organic layer OR1, upper electrode UE1 and cap layer CP1 are continuously formed while maintaining a vacuum environment.

Subsequently, the sealing layer SE1 is formed on the stacked film FL1 by depositing an inorganic insulating material. The sealing layer SE1 is formed by chemical vapor deposition (CVD). The sealing layer SE1 continuously covers the portions into which the stacked film FL1 is divided, and the partition 6.

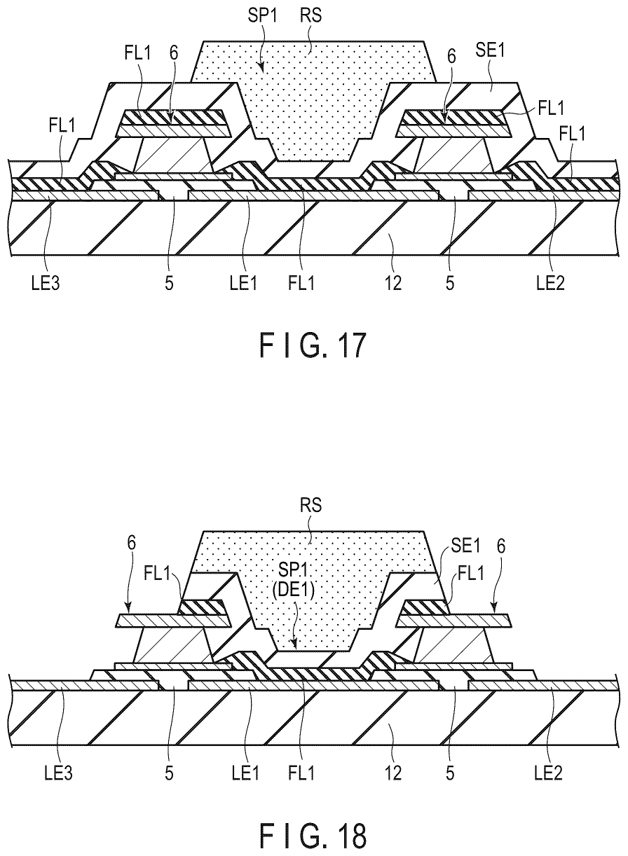

Subsequently, as shown in FIG. 17, a resist RS patterned into a predetermined shape is formed on the sealing layer SE1. The resist RS overlaps subpixel SP1 and part of the partition 6 around subpixel SP1.

Subsequently, as shown in FIG. 18, the sealing layer SE1 and the stacked film FL1 exposed from the resist RS are removed in series by performing etching using the resist RS as a mask. In this etching, the sealing layer SE1 exposed from the resist RS is removed. Subsequently, the cap layer CP1 exposed from the sealing layer SE1 is removed. Further, the upper electrode UE1 exposed from the cap layer CP1 is removed. Subsequently, the organic layer OR1 exposed from the upper electrode UE1 is removed. In this manner, the lower electrode LE2 of subpixel SP2 and the lower electrode LE3 of subpixel SP3 are exposed.

Subsequently, the resist RS is removed. By this process, the display element DE1 is formed in subpixel SP1.

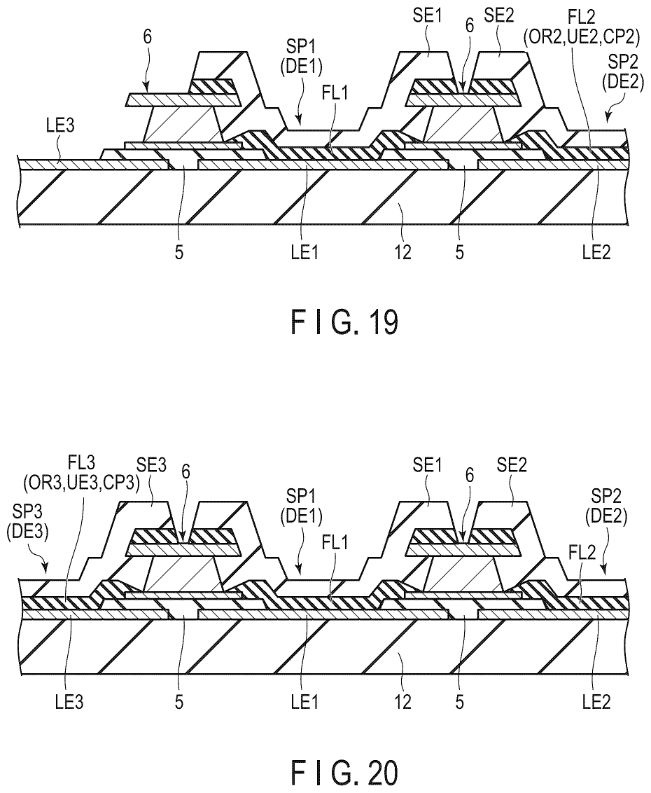

Subsequently, as shown in FIG. 19, the display element DE2 is formed. The procedure of forming the display element DE2 is similar to that of forming the display element DE1. Specifically, the stacked film FL2 is formed by forming the organic layer OR2 including the light emitting layer EM2, the upper electrode UE2 and the cap layer CP2 in order on the lower electrode LE2. Subsequently, the sealing layer SE2 is formed on the stacked film FL2. Subsequently, a resist is formed on the sealing layer SE2. The sealing layer SE2, the cap layer CP2, the upper electrode UE2 and the organic layer OR2 are patterned by etching using the resist as a mask. After this patterning, the resist is removed. By this process, the display element DE2 is formed in subpixel SP2, and the lower electrode LE3 of subpixel SP3 is exposed.

Subsequently, the display element DE3 is formed as shown in FIG. 20. The procedure of forming the display element DE3 is similar to that of forming the display element DE1. Specifically, the stacked film FL3 is formed by forming the organic layer OR3 including the light emitting layer EM3, the upper electrode UE3 and the cap layer CP3 in order on the lower electrode LE3. Subsequently, the sealing layer SE3 is formed on the stacked film FL3. Subsequently, a resist is formed on the sealing layer SE3. The sealing layer SE3, the cap layer CP3, the upper electrode UE3 and the organic layer OR3 are patterned by etching using the resist as a mask. After this patterning, the resist is removed. By this process, the display element DE3 is formed in subpixel SP3.

Subsequently, the resin layer 13, sealing layer 14 and resin layer 15 shown in FIG. 3 are formed in order. The display device DSP is completed by cutting the mother substrate 100 along the cut line CL. When the mother substrate 100 is cut along the cut line CL, the area on the inspection terminal TT side relative to the cut line CL in the area 100A shown in FIG. 6 remains in the display device DSP. Further, when the mother substrate 100 is cut along the cut line CL, the area on the left side of FIG. 7 relative to the cut line CL in the cross-sectional view shown in FIG. 7 remains in the display device DSP.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

As explained above, since the insulating layer 5 has the aperture OPB which overlaps the edge portion of the organic insulating layer IL, the local concentration of a stress near the edge portion E13 can be minimized or prevented. This configuration can minimize or prevent the insulating layer 5 from rising from the organic insulating layer IL.

When the stacked film FL1 is formed, the stacked film FL1 is partially divided by the surrounding partitions 7 having an overhang shape. Compared to a case where the stacked film FL1 is not divided by the surrounding partitions 7, the area of the continuous stacked film FL1 is reduced, and a stress which could be generated in the stacked film FL1 is dispersed. In addition, the insulating layer 5 and the stacked film FL1 are pressed by the surrounding partitions 7 and the sealing layer SE1. This configuration can minimize or prevent the stacked film FL1 from rising from the insulating layer 5.

When the organic insulating layer IL has a stepwise cross section in which the thickness decreases toward the aperture OPA, the formation of a steep step can be prevented. The elongation of the organic insulating layer IL is less as the thickness decreases. Thus, when the stacked film FL1 is formed on the organic insulating layer IL, the distortion of the stacked film FL1 is less, and the local concentration of stress can be minimized or prevented in the stacked film FL1. This configuration can minimize or prevent the stacked film FL1 from rising from the insulating layer 5 and the organic insulating layer IL when the stacked film FL1 is formed near the aperture OPB.

Here, this specification explains problems which could occur when the stacked film FL1 and the insulating layer 5 rise from the base and are broken. The insulating layer 5 and stacked film FL1 separated from the base could float inside the manufacturing device as foreign substances and could be a contaminant source. If the floating foreign substances are attached to the processing substrate, various defects could be caused.

The embodiment can minimize or prevent the separation of the insulating layer 5 and the stacked film FL1. This configuration can minimize or prevent the contamination of the manufacturing device and the generation of undesired foreign substances. In this manner, the reduction in reliability can be minimized or prevented.

Even in a case where the stacked film FL1 is replaced by the stacked film FL2 for forming the display element DE2, or a case where the stacked film FL1 is replaced by the stacked film FL3 for forming the display element DE3, similar effects are obtained.

In the area where the organic insulating layer IL is not present, the insulating layers 111, 112 and 113 which are inorganic insulating layers similar to the insulating layer 5 in kind are located immediately under the insulating layer 5. For this reason, when dry etching for forming the aperture OPB in the insulating layer 5 is performed, the insulating layers 111, 112 and 113 might be also removed.

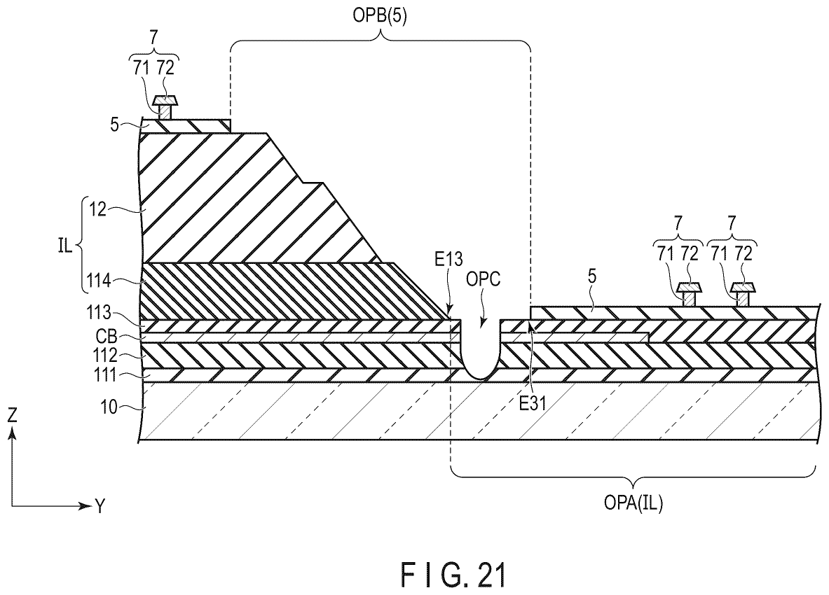

FIG. 21 is a cross-sectional view for explaining the problems of a comparative example.

In the comparative example shown in the figure, the protective layer PR is not provided immediately above the connection line CB. In this case, in the area where the organic insulating layer IL is not present immediately under the insulating layer 5, when the aperture OPB is formed in the insulating layer 5, an aperture OPC which penetrates the insulating layers 111, 112 and 113 might be formed and further penetrate the connection line CB.

When this defect occurs, the connection line CB is broken. Thus, the electrical connection between the TEG terminal TG and the inspection terminal TT cannot be assured, thereby causing a problem in the subsequent inspection process. Further, although not shown in the figure, the connection line CA is also broken in a manner similar to that of the connection line CB. In this manner, the function of the connection line CA as a short-circuit line (short ring) in the manufacturing process is lost. In addition, the connection line CA and the connection line CB are exposed in the aperture OPC. Thus, when a conductive material remains in the aperture OPC in the subsequent process, an undesired short circuit is caused between the connection line CA and the connection line CB.

In the embodiment, as shown in FIG. 6 and FIG. 7, the protective layers PR overlap the connection lines CA and CB, and cover the insulating layer 113 located immediately above these connection lines. Therefore, when the apertures OPB are formed in the insulating layer 5, the insulating layer 113 located immediately above the connection lines is protected, thereby preventing the formation of the undesired aperture OPC. This configuration can prevent the breaking of the connection lines and the exposure of the connection lines from the insulating layer 113. In this manner, the reduction in reliability can be minimized or prevented.

Each of the protective layers PR1 and PR2 is formed of a material different from inorganic insulating materials, for example, a semiconductor or a metal material. Thus, each protective layer PR functions as an etching stopper in the dry etching process for processing the insulating layer 5. The protective layer PR2 is formed of a material different from that of the protective layer PR1, for example, the material for forming the lower electrodes, and covers the protective layer PR1. Thus, the protective layer PR1 is protected by the protective layer PR2 when the lower electrodes are patterned.

Further, the connection lines CA and CB located in the area which does not overlap the organic insulating layer IL are bent so as to bypass the surrounding partitions 7 in plan view as shown in FIG. 6. Therefore, even if the connection lines are exposed, they do not overlap the surrounding partitions 7, thereby preventing an undesired short circuit via the surrounding partitions 7.

Now, this specification explains the effect of the structure in which the edge portion E13 and the edge portion E31 have zigzag shapes.

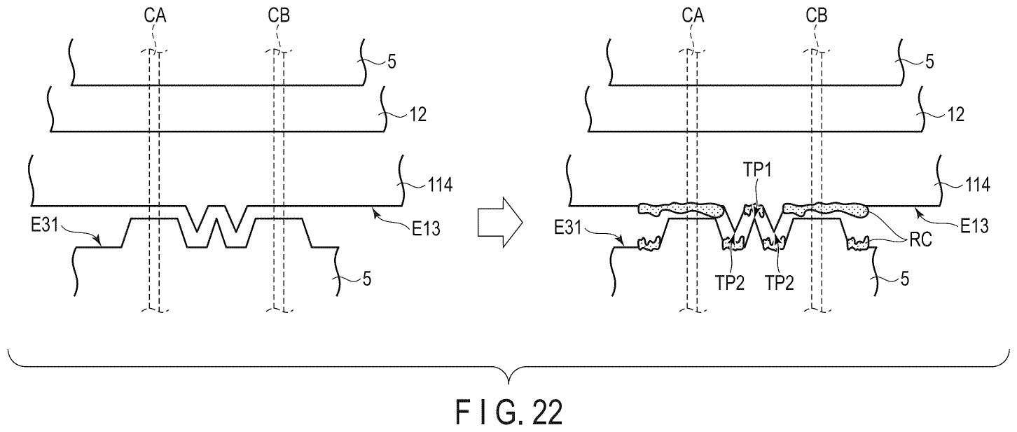

FIG. 22 is a diagram for explaining one of the effects of the embodiment.

As shown on the left side of the figure, the edge portion E13 and the edge portion E31 have zigzag shapes between the connection line CA and the connection line CB.

As shown on the right side of the figure, when a conductive material RC remains along the edge portion E13 in the subsequent manufacturing process, the conductive material RC is divided in the taper portions TP2. When the conductive material RC remains along the edge portion E31, the conductive material RC is divided in the taper portion TP1. Thus, as explained with reference to FIG. 21, even if the connection line CA and the connection line CB are exposed from the aperture OPC, an undesired short circuit via the conductive material RC can be prevented.

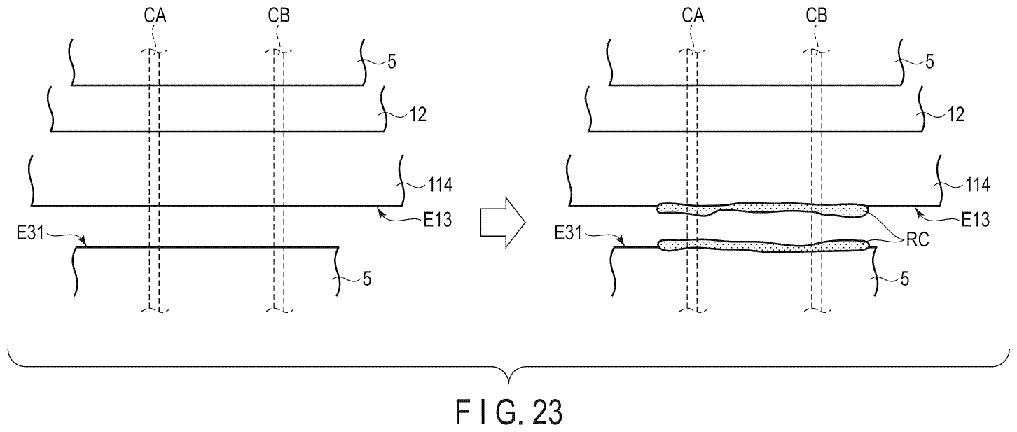

FIG. 23 is a cross-sectional view for explaining the problems of the comparative example.

As shown on the left side of the figure, the edge portion E13 and the edge portion E31 are linearly formed between the connection line CA and the connection line CB.

As shown on the right side of the figure, when a conductive material RC remains along the edge portion E13 and the edge portion E31 in the subsequent manufacturing process, the conductive material RC is continuously formed between the connection line CA and the connection line CB. Thus, as explained with reference to FIG. 21, when the connection line CA and the connection line CB are exposed from the aperture OPC, the short circuit of the connection line CA and the connection line CB is caused via the conductive material RC.

Now, this specification explains another configuration example of the display device DSP.

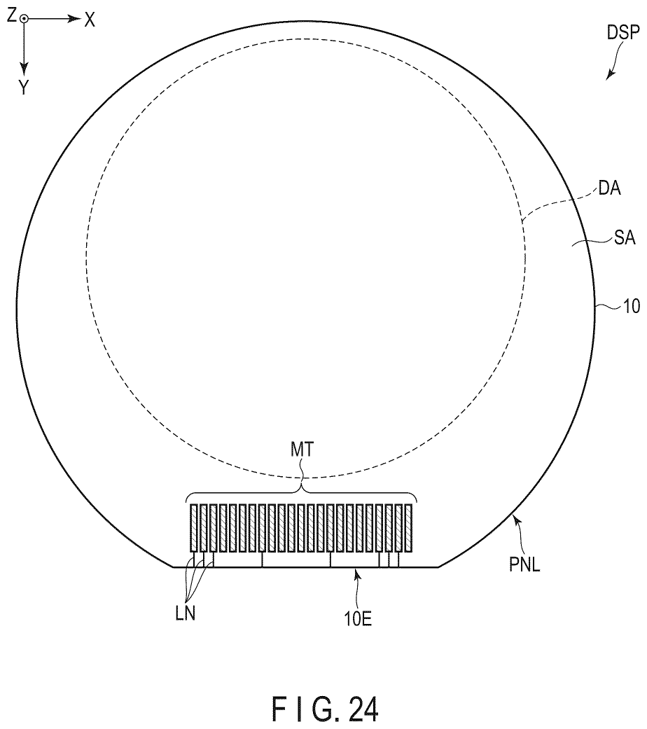

FIG. 24 is a diagram showing another configuration example of the display device DSP.

The configuration example shown in FIG. 24 is different from that shown in FIG. 1 in respect that the display area DA is formed as substantially a circular area, and the outer shape of the substrate 10 is formed into substantially an arc shape. The configuration of the display area DA is as explained with reference to FIG. 1 to FIG. 3.

The surrounding area SA comprises a plurality of mount terminals MT. In the example shown in the figure, the substrate 10 has a linear substrate end 10E, and the mount terminals MT are provided along the substrate end 10E and are arranged in the first direction X. It should be noted that the inspection terminals TT shown in FIG. 1 are not provided in the surrounding area SA in the example shown in FIG. 24.

The mount terminals MT are terminals electrically connected to signal sources such as flexible printed circuits and IC chips and are electrically connected to the various lines (scanning lines, signal lines, power lines, lines for touch sensors and the like) of the display area DA. The mount terminals MT are connected to lines LN which extend toward the substrate end 10E.

Now, this specification explains the mother substrate 100 for manufacturing a plurality of display devices DSP comprising the structure shown in FIG. 24 in a lump.

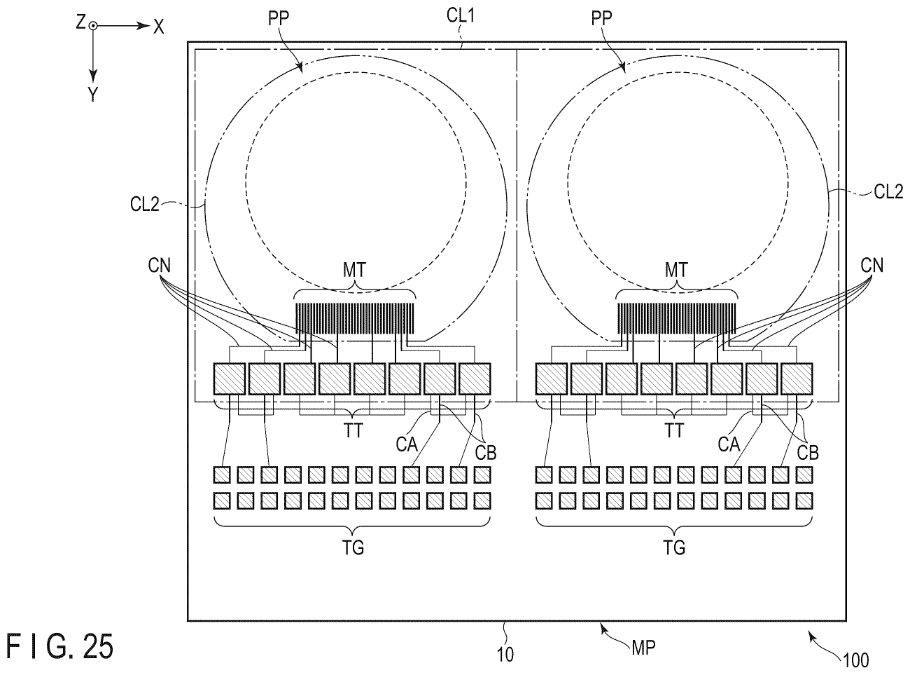

FIG. 25 is a plan view showing a configuration example of the mother substrate 100.

The mother substrate 100 comprises a plurality of panel portions PP and a margin portion MP located on an external side relative to these panel portions PP on a large substrate 10. The large substrate 10 is formed into, for example, a rectangular shape. The example of the figure shows two panel portions PP as a plurality of panel portions PP. However, more panel portions may be arrayed in matrix in the first direction X and the second direction Y.

In the figure, the one-dot chain lines are primary cut lines CL1, and the two-dot chain lines are final cut lines CL2. The panel portions PP are extracted by cutting the mother substrate 100 along the final cut lines CL2 after cutting the mother substrate 100 along the primary cut lines CL1. Each of the extracted panel portions PP corresponds to the display panel PNL shown in FIG. 24.

The margin portion MP comprises inspection terminals TT and TEG terminals TG. The inspection terminals TT are located between the primary cut lines CL1 and the final cut lines CL2. The TEG terminals TG are located on an external side relative to the primary cut lines CL1.

Each connection line CA is provided in the margin portion MP and electrically connects adjacent inspection terminals TT to each other. Each connection line CB is provided in the margin portion MP and electrically connects the TEG terminal TG and the inspection terminal TT to each other. Each connection line CN is provided over the panel portion PP and the margin portion MP and electrically connects the inspection terminal TT and the mount terminal MT to each other.

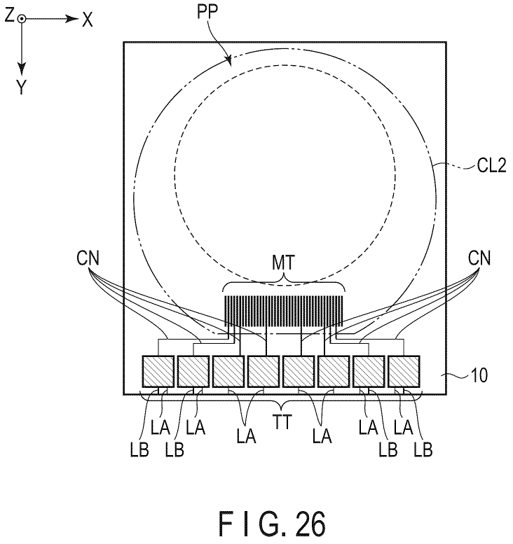

FIG. 26 is a plan view showing the substrate 10 after the mother substrate 100 is cut along the primary cut lines CL1.

When the mother substrate 100 is cut along the primary cut lines CL1, the substrate 10 is formed into a rectangular shape, and part of each connection line CA remains in the substrate 10 as the lines LA, and part of each connection line CB remains in the substrate 10 as the line LB.

Subsequently, the mother substrate 100 is cut along the final cut line CL2. At this time, part of each connection line CN remains in the display panel PNL as the line LN shown in FIG. 24.

When the vicinity of the intersection of each connection line CN and the final cut line CL2 is enlarged, in a manner similar to that of the example shown in FIG. 6, each of the protective layers PR intersects with the edge portions E11, E12, E13 and E31 or the edge portions E32, E23, E22 and E21 and overlaps the connection line CN. Further, each of the edge portions E13, E31, E23 and E32 is bent so as to have a zigzag shape between adjacent connection lines CN. Thus, effects similar to those of the above configuration example are obtained.

In the embodiment described above, for example, each line LA or part of each connection line CA, each line LB or part of each connection line CB and each line LN or part of each connection line CN correspond to a plurality of lines. Further, each line LA or part of each connection line CA corresponds to a first line, and each line LB or part of each connection line CB corresponds to a second line.

The insulating layer 113 corresponds to a first inorganic insulating layer. The insulating layer 5 corresponds to a second inorganic insulating layer. The insulating layer 114 corresponds to the first layer of the organic insulating layer IL. The insulating layer 12 corresponds to the second layer of the organic insulating layer IL.

In each protective layer PR, the protective layer PR1 corresponds to a first protective layer, and the protective layer PR2 corresponds to a second protective layer. In each surrounding partition 7, the lower portion 71 corresponds to a first lower portion, and the upper portion 72 corresponds to a first upper portion. In the partition 6, the lower portion 61 corresponds to a second lower portion, and the upper portion 62 corresponds to a second upper portion.

In the process of manufacturing a display element such as described in the Background section, a technique which minimizes or prevents the reduction in reliability may be desirable.

As explained above, one or more embodiments of the present disclosure can provide a display device and a manufacturing method thereof such that the reduction in reliability can be minimized or prevented.

All of the display devices and manufacturing methods thereof that can be implemented by a person of ordinary skill in the art such as those described above come within the scope of the present disclosure as long as they are in keeping with the spirit of the present disclosure.

Various modification examples which may be conceived by a person of ordinary skill in the art can also fall within the scope of the present disclosure including one or more embodiments thereof. For example, even if a person of ordinary skill in the art modifies the above embodiments by adding or deleting a structural element or changing the design of a structural element, or by adding or omitting a step or changing the condition of a step, all of the modifications fall within the scope of the present disclosure as long as they are in keeping with the spirit of the disclosure or one or more embodiments thereof.

Further, other effects which may be obtained from the above embodiments and are self-explanatory from the descriptions of the specification or can be conceived by a person of ordinary skill in the art are considered as the effect(s) of one or more embodiments of the present disclosure as a matter of course.

What is claimed is:

1. A display device comprising:
a substrate;
a first inorganic insulating layer over a display area to display an image and a surrounding area located on an external side relative to the display area above the substrate;
an organic insulating layer on the first inorganic insulating layer, the organic insulating layer defining a first aperture in the surrounding area;
a lower electrode on the organic insulating layer in the display area;
an organic layer on the lower electrode and including a light emitting layer;
an upper electrode on the organic layer;
a second inorganic insulating layer on the organic insulating layer, the second inorganic insulating layer defining at least one second aperture which exposes an edge portion of the organic insulating layer in the surrounding area;
a plurality of lines between the substrate and the first inorganic insulating layer and which intersect with the edge portion in a plan view; and
a plurality of protective layers which intersect the edge portion in the plan view, wherein
one of the protective layers is over a portion of one of the plurality of lines and overlaps a portion of the first inorganic insulating layer exposed from the organic insulating layer in the first aperture.

2. The display device of claim 1, further comprising:
a mount terminal in the surrounding area and electrically connected to a signal source; and
an inspection terminal electrically connected to the mount terminal, wherein
at least one of the plurality of lines is connected to the inspection terminal.

3. The display device of claim 2, wherein
the plurality of lines comprise a first line formed of a semiconductor material and a second line formed of a metal material.

4. The display device of claim 3, wherein
the first line and the second line are connected to a same inspection terminal, and
in the plan view, the edge portion of the organic insulating layer and an edge portion of the second inorganic insulating layer face each other, and have zigzag shapes between the first line and the second line.

5. The display device of claim 1, wherein
each of the protective layers includes:
a first protective layer formed of a metal material and in contact with the first inorganic insulating layer; and
a second protective layer formed of a same material as the lower electrode and on the first protective layer.

6. The display device of claim 5, wherein
the organic insulating layer includes:
a first layer on the first inorganic insulating layer; and
a second layer on the first layer,
the first protective layer has a first end portion between the first layer and the second layer, and a second end portion between the first inorganic insulating layer and the second protective layer, and
the second protective layer has a first end portion between the second layer and the second inorganic insulating layer, and a second end portion between the first inorganic insulating layer and the second inorganic insulating layer.

7. The display device of claim 1, wherein
the organic insulating layer has a stepwise cross section in which a thickness decreases in an area which overlaps the first aperture.

8. The display device of claim 1, further comprising a plurality of surrounding partitions in the surrounding area, wherein
each of the surrounding partitions has a first lower portion on the second inorganic insulating layer and a first upper portion on the first lower portion and protruding from a side surface of the first lower portion, and
the plurality of lines in an area which does not overlap the organic insulating layer are bent so as to bypass the surrounding partitions in the plan view.

9. The display device of claim 8, further comprising, in the display area, a partition which has a second lower portion on the second inorganic insulating layer and formed of a conductive material, and a second upper portion on the second lower portion and protruding from a side surface of the second lower portion, wherein
the second lower portion is formed of a same material as the first lower portion,
the second upper portion is formed of a same material as the first upper portion,
the lower electrode, the organic layer, and the upper electrode are surrounded by the partition, and
the upper electrode is in contact with the second lower portion of the partition.

10. The display device of claim 9, further comprising:
a cap layer on the upper electrode and surrounded by the partition; and
a sealing layer formed of an inorganic insulating material on the cap layer, wherein
an end portion of the sealing layer is on the partition.

11. The display device of claim 1, wherein
the second inorganic insulating layer defines two second apertures in a side sectional view, and
a portion of each of the second apertures overlaps the first aperture.

12. The display device of claim 1, wherein
the second inorganic layer is on the protective layers and on the first inorganic insulating layer in the first aperture in a side sectional view.

13. The display device of claim 1, wherein
in a side sectional view, portions of the second inorganic insulating layer that define opposite sides of the second aperture are on and over a corresponding one of the protective layers.

14. A display device comprising:
a substrate;
a first inorganic insulating layer over a display area to display an image and a surrounding area located on an external side relative to the display area above the substrate;
an organic insulating layer on the first inorganic insulating layer, the organic insulating layer defining a first aperture in the surrounding area;
a lower electrode on the organic insulating layer in the display area;
an organic layer on the lower electrode and including a light emitting layer;
an upper electrode on the organic layer;
a second inorganic insulating layer on the organic insulating layer, the second inorganic insulating layer defining a plurality of second apertures each of which exposes an edge portion of the organic insulating layer in the surrounding area;
a plurality of lines between the substrate and the first inorganic insulating layer and which intersect with the edge portion in a plan view; and
a plurality of protective layers which intersect the edge portion in the plan view, wherein
one of the protective layers overlaps a portion of the first inorganic insulating layer exposed from the organic insulating layer in the first aperture,
a portion of each of the second apertures overlaps the first aperture, and
the second inorganic layer is on the protective layers and on the first inorganic insulating layer in the first aperture.

15. The display device of claim 1, wherein each of the protective layers includes:
a first protective layer in contact with the first inorganic insulating layer; and
a second protective layer on the first protective layer.
the organic insulating layer includes:
a first layer on the first inorganic insulating layer; and
a second layer on the first layer,
the first protective layer has a first end portion between the first layer and the second layer, and a second end portion between the first inorganic insulating layer and the second protective layer, and
the second protective layer has a first end portion between the second layer and the second inorganic insulating layer, and a second end portion between the first inorganic insulating layer and the second inorganic insulating layer.

16. A manufacturing method of a display device, comprising:
forming a line above a substrate;
forming a first inorganic insulating layer on the line;
forming an organic insulating layer on the first inorganic insulating layer;
forming a lower electrode on the organic insulating layer;
forming a protective layer which faces the line and overlaps the first inorganic insulating layer exposed from the organic insulating layer;
forming a second inorganic insulating layer which covers the organic insulating layer and the protective layer;
forming an aperture which overlaps an edge portion of the organic insulating layer in the second inorganic insulating layer;
forming an organic layer on the lower electrode; and
forming an upper electrode on the organic layer,
wherein
the line is formed of a semiconductor or a metal material.

17. The manufacturing method of claim 16, wherein
when the organic insulating layer is formed, the edge portion of the organic insulating layer is formed so as to have a zigzag shape, and
when the aperture is formed in the second inorganic insulating layer, an end portion of the second inorganic insulating layer facing the edge portion of the organic insulating layer is formed so as to have a zigzag shape.

18. The manufacturing method of claim 16, wherein
the forming the organic insulating layer includes:
forming a first layer on the first inorganic insulating layer; and
forming a second layer on the first layer, and
the forming the protective layer includes:
forming a first protective layer which is in contact with the first inorganic insulating layer and extends to an upper side of the first layer before forming the second layer; and
forming a second protective layer which overlaps the first protective layer and extends to an upper side of the second layer after forming the second layer,
the first protective layer is formed of a metal material, and
the second protective layer is formed of a same material as the lower electrode.

19. The manufacturing method of claim 16, further comprising:
forming a surrounding partition which has a first lower portion located on the second inorganic insulating layer, and a first upper portion located on the first lower portion and protruding from a side surface of the first lower portion; and
forming a partition which has a second lower portion located on the second inorganic insulating layer, and a second upper portion located on the second lower portion and protruding from a side surface of the second lower portion, wherein
the first lower portion and the second lower portion is formed by using a same material in a same process, and
the first upper portion and the second upper portion is formed by using a same material in a same process.

20. The manufacturing method of claim 19, further comprising:
forming a cap layer on the upper electrode, wherein
the organic layer, the upper electrode and the cap layer are formed by vapor deposition using the partition as a mask;
forming a sealing layer on the cap layer by using an inorganic insulating material;
forming a resist patterned into a predetermined shape on the sealing layer; and
removing the sealing layer, the cap layer, the upper electrode and the organic layer exposed from the resist by performing etching using the resist as a mask.
